(19) United States
(12) Patent Application Publication
(10) Pub. No.: US 2023/0154879 A1
(43) Pub. Date: May 18, 2023

(54) SEMICONDUCTOR DEVICE, A PACKAGE SUBSTRATE, AND A SEMICONDUCTOR PACKAGE

(71) Applicant: SK hynix Inc., Icheon-si Gyeonggi-do (KR)

(72) Inventors: Si Yun KIM, Icheon-si Gyeonggi-do (KR); Kang Hun KIM, Icheon-si Gyeonggi-do (KR); Jun Yong SONG, Icheon-si Gyeonggi-do (KR)

(73) Assignee: SK hynix Inc., Icheon-si Gyeonggi-do (KR)

(21) Appl. No.: 17/717,674

(22) Filed: Apr. 11, 2022

(30) Foreign Application Priority Data
Nov. 16, 2021 (KR) 10-2021-0157869

(51) Int. Cl. H01L 23/00

(52) U.S. Cl. CPC H01L 24/14; H01L 24/16; H01L 24/17; H01L 24/05; H01L 24/13; H01L 2924/3841; H01L 2224/1403; H01L 2224/1703; H01L 2224/16227; H01L 2224/0401; H01L 2224/05624; H01L 2224/13147; H01L 2224/14133; H01L 2224/0613; H01L 24/06; H01L 2224/05583; H01L 2224/05647; H01L 2224/05666; H01L 2924/014; H01L 24/03; H01L 24/11; H01L 2224/1146; H01L 2224/11474; H01L 2224/0361; H01L 2224/11849; H01L 2224/81203; H01L 24/81

(57) ABSTRACT

A semiconductor device is provided. The semiconductor device includes a substrate, input and output (I/O) pads disposed at an upper portion of the semiconductor substrate, and first bump pillars disposed over the I/O pads. The first bump pillars are selectively arranged over some of the I/O pads in a first horizontal direction.

### CROSS-REFERENCE TO RELATED APPLICATIONS

The present application claims priority to Korean Patent Application No. 10-2021-0157869, filed on Nov. 16, 2021, which is herein incorporated by reference in its entirety.

### BACKGROUND

### 1. Technical Field

The present disclosure provides semiconductor devices having bump pillars and methods of manufacturing the semiconductor devices, package substrates having land pillars, and semiconductor packages having the semiconductor devices and the package substrates.

### 2. Related Art

A distance between input and output (I/O) pads of a semiconductor device and a distance between bump lands of a package substrate are gradually decreasing. Accordingly, a gap between solder bumps bonding and connecting the semiconductor device and the package substrate is getting smaller and a problem such as a bridge between the solder bumps occurs.

### SUMMARY

A semiconductor device according to an embodiment of the present disclosure may include a substrate, input and output (I/O) pads disposed at an upper portion of the semiconductor substrate, and first bump pillars disposed over the I/O pads. The first bump pillars are selectively arranged over some of the I/O pads in a first horizontal direction.

A semiconductor package according to an embodiment of the present disclosure may include a semiconductor device stacked over a package substrate. The semiconductor device may include a semiconductor substrate, input and output (I/O) pads disposed adjacent to one surface of the semiconductor substrate, and first bump pillars disposed over the I/O pads. The first bump pillars may be selectively arranged over some of the I/O pads in a first horizontal direction. The package substrate may include a base layer, and bump lands disposed at an upper portion of the base layer. Each of the bump lands may be vertically aligned with each of the I/O pads.

A semiconductor package according to an embodiment of the present disclosure may include a semiconductor device stacked over a package substrate. The semiconductor device may include a semiconductor substrate, input and output (I/O) pads disposed adjacent to one surface of the semiconductor substrate, and first bump pillars disposed over the input/out pads. The first bump pillars may be arranged to skip one by one over the I/O in a first horizontal direction. The package substrate may include a base layer, bump lands disposed at an upper portion of the base layer, and first land pillars disposed over the bump lands. The first land pillars may be arranged to skip one by one over the bump lands in the first horizontal direction. Each of the first bump pillars and each of the first land pillars may be exclusively arranged not to be vertically aligned with each other.

### BRIEF DESCRIPTION OF THE DRAWINGS

FIG. 1A is a longitudinal cross-sectional view showing a semiconductor device according to an embodiment of the present disclosure, and FIGS. 1B and 1C are perspective views of the semiconductor device.

FIG. 2A is a longitudinal cross-sectional view illustrating a semiconductor device according to an embodiment of the present disclosure, and FIGS. 2B and 2C are perspective views of the semiconductor device.

FIGS. 3A and 3B are longitudinal cross-sectional views schematically illustrating package substrates according to embodiments of the present disclosure.

FIGS. 4A, 4B, 4C, and 4D are longitudinal cross-sectional views schematically illustrating semiconductor packages according to embodiments of the present disclosure.

FIGS. 5A, 5B, 5C, and 5D are longitudinal cross-sectional views illustrating a method of manufacturing a semiconductor device according to an embodiment of the present disclosure, and FIGS. 5E, 5F, 5G, 5H, 5I, 5J, and 5K are cross-sectional views illustrating methods manufacturing semiconductor packages according to embodiments of the present disclosure using the semiconductor device.

FIG. 6A is a longitudinal cross-sectional view illustrating a method of manufacturing a semiconductor device according to an embodiment of the present disclosure, and FIGS. 6B, 6C, 6D, 6E, and 6F are cross-sectional views illustrating a method of manufacturing semiconductor packages according to embodiments of the present disclosure using the semiconductor device.

### DETAILED DESCRIPTION

Embodiments of the present disclosure will be described below in more detail with reference to the accompanying drawings. The present disclosure may, however, be embodied in different forms and should not be construed as limited to the embodiments set forth herein. Throughout the disclosure, like reference numerals refer to like parts throughout the various figures and embodiments of the present invention.

It will be understood that, although the terms “first” and/or “second” may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

Other expressions that explain the relationship between elements, such as “between”, “directly between”, “adjacent to” or “directly adjacent to” should be construed in the same way.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer with no intervening layers but also to a case where intervening layers are formed between the first and second layers. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

Embodiments of the present disclosure provide semiconductor devices having bump pillars selectively disposed thereon and methods of manufacturing the semiconductor devices.

Embodiments of the present disclosure provide semiconductor devices having first bump pillars and second bump pillars having different heights, and methods of manufacturing the semiconductor device.

Embodiments of the present disclosure provide package substrates having land pillars selectively disposed thereon.

Embodiments of the present disclosure provide package substrates having first land pillar and second land pillars having different heights.

Embodiments of the present disclosure provide semiconductor packages in which the semiconductor devices and the package substrates are bonded.

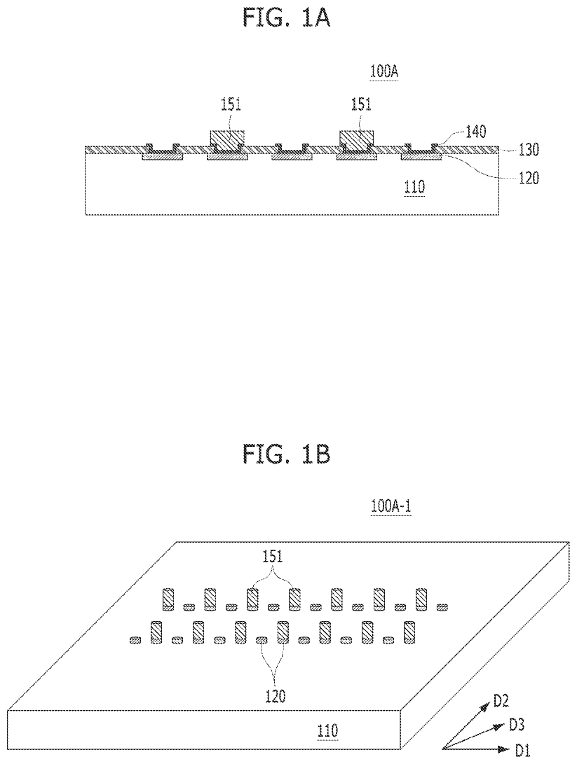

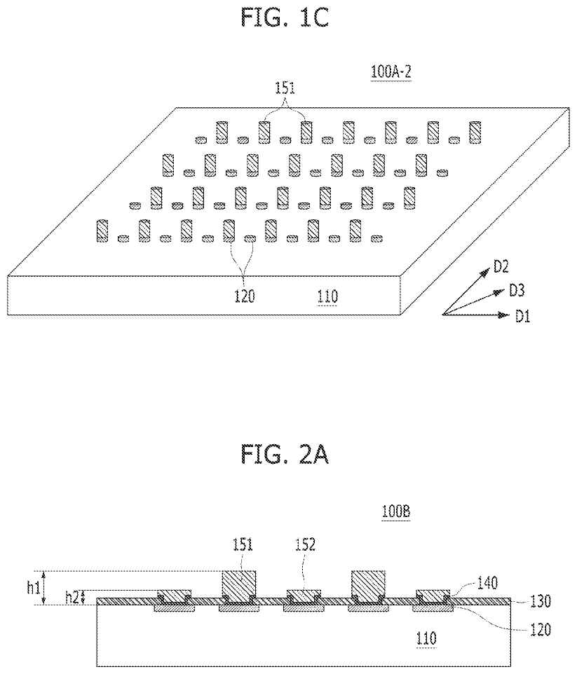

FIG. 1A is a longitudinal cross-sectional view showing a semiconductor device 100A according to an embodiment of the present disclosure, and FIGS. 1B and 1C are perspective views of the semiconductor device 100A. Referring to FIGS. 1A to 1C, a semiconductor device 100A according to an embodiment of the present disclosure may include a semiconductor substrate 110 having input and output (I/O) pads 120, a passivation layer 130, barrier layers 140, and a first bump pillars 151.

The semiconductor substrate 110 may include a silicon wafer, and internal circuits and a plurality of insulating layers formed on a surface of the silicon wafer. The internal circuits may include a plurality of transistors, a plurality of metal vias, multi-layered metal interconnections, and the I/O pads 120.

The I/O pads 120 may be disposed in an upper portion of the semiconductor substrate 110 adjacent to a top surface of the semiconductor substrate 110. Top surfaces of the I/O pads 120 may be exposed. The I/O pads 120 may include a metal such as aluminum (Al).

The passivation layer 130 may be formed on the top surfaces of the semiconductor substrate 110 to partially expose the top surfaces of the I/O pads 120. The passivation layer 130 may include an insulating material. For example, the passivation layer 130 may include a polymeric organic material such as polyimide isoindro quindzoline (PIQ), or an inorganic material such as silicon nitride (SiN) or silicon oxide (SiO₂).

The barrier layers 140 may be formed on the I/O pads 120. Ends of the barrier layers 140 may extend onto the passivation layer 130. The barrier layers 140 may include a metal layer. The barrier layers 140 may include a lower layer including a barrier metal layer such as a titanium (Ti) layer and an upper layer including a seed metal layer such as a copper (Cu) layer. For example, the barrier layers 140 may include a titanium/copper (Ti/Cu) layer.

The first bump pillars 151 may be selectively formed on some of the I/O pads 120 or some of the barrier layers 140. For example, the first bump pillars 151 may be arranged to skip every other one of the I/O pads 120 or the barrier layers 140. The first bump pillars 151 may include a metal such as copper. In an embodiment, the first bump pillars 151 may be alternately disposed on the I/O pads 120 or the barrier layers 140 by serially skipping every other I/O pad 120 or the barrier layer 140 as, for example, shown in FIG. 1A or FIG. 1B.

Referring to FIG. 1B, the I/O pads 120 may be arranged on one or more rows in a first horizontal direction D1. For example, as shown in FIG. 1B, the I/O pads 120 may include the I/O pads 120 arranged side-by-side on two rows in the first horizontal direction D1. The first bump pillars 151 may be selectively disposed on some of the I/O pads 120 in the first horizontal direction D1. For example, the first bump pillars 151 may be arranged to skip every other one of the I/O pads 120 in the first horizontal direction D1. The passivation layer 130 and the barrier layers 140 shown in FIG. 1A are omitted to make it easier to understand the arrangements of the I/O pads 120 and the first bump pillars 151.

Referring to FIG. 1C, the I/O pads 120 may be arranged on a plurality of rows and columns in the first horizontal direction D1 and a second horizontal direction D2. For example, the I/O pads 120 may be arranged in a matrix form. The first bump pillars 151 may be selectively disposed on some of the I/O pads 120 in the first horizontal direction D1 and the second horizontal direction D2. For example, the first bump pillars 151 may be arranged to skip every other one of the I/O pads 120 in the first horizontal direction D1 and the second horizontal direction D2. The first horizontal direction D1 and the second horizontal direction D2 may be perpendicular to each other. In an embodiment, the first bump pillars 151 may be alternately disposed on the I/O pads 120 or the barrier layers 140 by serially skipping every other I/O pad 120 or the barrier layer 140 for at least one of the first direction D1 and the second direction D2 as, for example, shown in FIG. 1C.

As shown in FIGS. 1B and 1C, the first bump pillars 151 may be arranged to be aligned on virtual parallel diagonal lines in the diagonal direction D3.

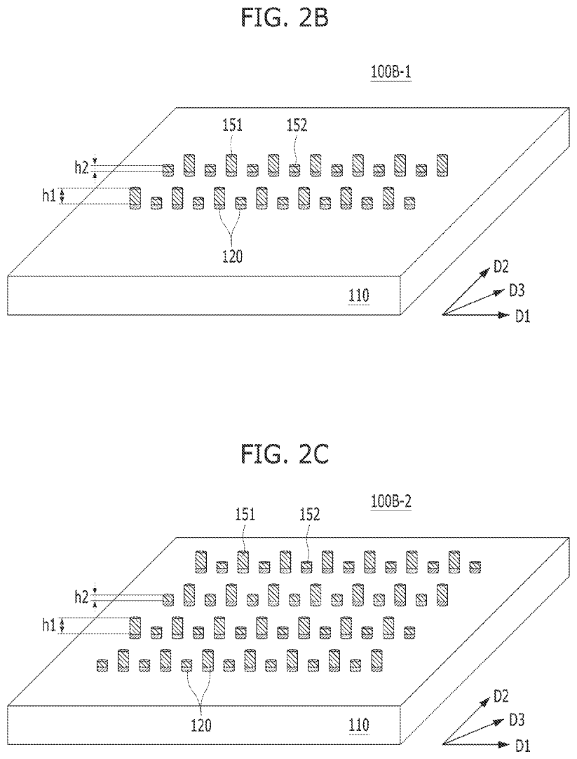

FIG. 2A is a longitudinal cross-sectional view illustrating a semiconductor device 100B according to an embodiment of the present disclosure, and FIGS. 2B and 2C are perspective views of the semiconductor device 100B. Referring to FIGS. 2A to 2C, a semiconductor device 100B according to an embodiment of the present disclosure may include a semiconductor substrate 110 having I/O pads 120, a passivation layer 130, barrier layers 140, first bump pillars 151, and second bump pillars 152. The first bump pillars 151 may have a first height h1, and the second bump pillars 152 may have a second height h2. The first height h1 and the second height h2 may be different from each other. For example, the first height h1 may be greater than the second height h2. (h1>h2) The first bump pillars 151 and the second bump pillars 152 may be alternately arranged in the first horizontal direction D1.

Referring to FIG. 2B, the I/O pads 120 may be arranged on one or more rows in the first horizontal direction D1. For example, as shown in FIG. 2B, the I/O pads 120 may be arranged side-by-side on two rows in the first horizontal direction D1. The first bump pillars 151 and the second bump pillars 152 may be alternately arranged on the I/O pads 120 in the first horizontal direction D1. The passivation layer 130 and the barrier layers 140 are omitted to make it easier to understand the arrangements of the I/O pads 120, the first bump pillars 151, and the second bump pillars 152.

Referring to FIG. 2C, the I/O pads 120 may be arranged on a plurality of rows and columns in the first horizontal direction D1 and the second horizontal direction D2. For example, the I/O pads 120 may be arranged in a matrix form. The first bump pillars 151 and the second bump pillars 152 may be alternately arranged in the first horizontal direction D1 and the second horizontal direction D2.

As shown in FIGS. 2B and 2C, the first bump pillars 151 and the second bump pillars 152 may be arranged to be aligned on virtual parallel diagonal lines in the diagonal direction D3, respectively.

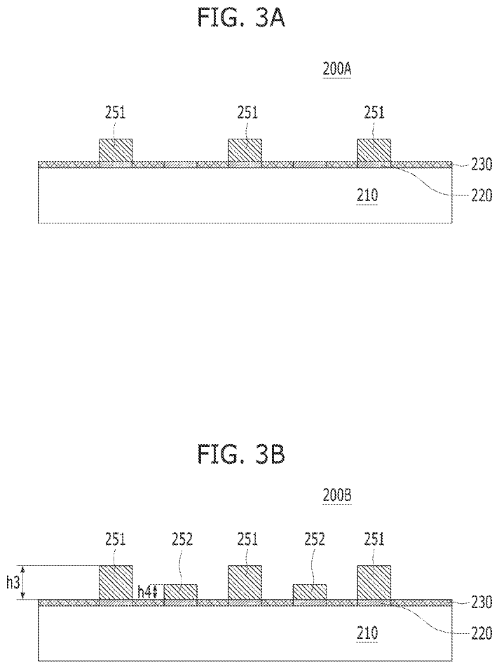

FIGS. 3A and 3B are longitudinal cross-sectional views schematically illustrating package substrates 200A and 200B according to embodiments of the present disclosure. Referring to FIG. 3A, a package substrate 200A according to an embodiment of the present disclosure may include a base layer 210 having bump lands 220, a solder resist layer 230, and first land pillars 251.

The base layer 210 may include a printed circuit board (PCB). For example, the base layer 210 may include prepreg layers and metal layers alternatively stacked. The bump lands 220 may be disposed at an upper portion of the base layer 210 adjacent to a top surface of the base layer 210. Top surfaces of the bump lands 220 may be exposed. The bump lands 220 may include a metal such as copper (Cu).

The solder resist layer 230 may be formed on the base layer 210 to partially expose the top surfaces of the bump lands 220.

The first land pillars 251 may be selectively formed on some of the bump lands 220. The first land pillars 251 may be alternately disposed to skip every other one of the bump lands 220. The first land pillars 251 may include a metal such as copper (Cu). In an embodiment, the first land pillars 251 may be alternately disposed on the bump lands 220 by serially skipping every other bump land 220 as for example shown in FIG. 3B.

Referring to FIG. 3B, a package substrate 200B according to an embodiment of the present disclosure may include a base layer 210 having bump lands 220, a solder resist layer 230, first land pillars 251, and second land pillars 252. The first land pillars 251 may have a third height h3, and the second land pillars 252 may have a fourth height h4. The third height h3 and the fourth height h4 may be different from each other. For example, the third height h3 may be greater than the fourth height h4. (h3>h4) The first land pillars 251 and the second land pillars 252 may be alternately arranged in a horizontal direction.

A height difference between the first height h1 of the first bump pillars 151 and the second height h2 of the second bump pillars 152 in FIGS. 2A to 2C may be substantially same as a difference between the third height h3 of the first land pillars 251 and the fourth height h4 of the second land pillars 252 in FIG. 3B (h1−h2≈h3−h4). In some embodiments, the heights may be referred to as vertical heights.

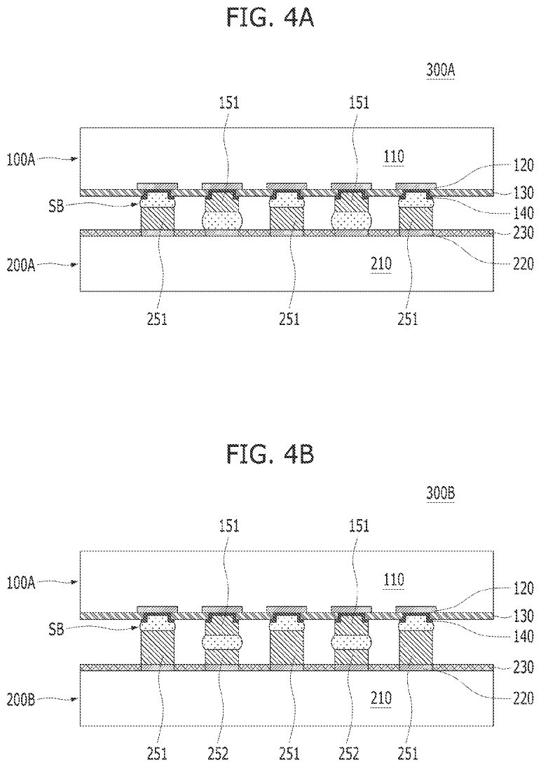

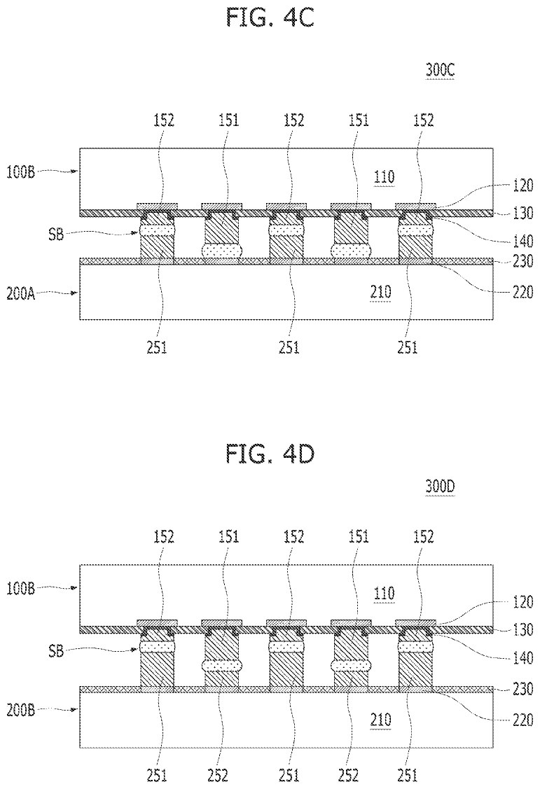

FIGS. 4A to 4D are longitudinal cross-sectional views schematically illustrating semiconductor packages 300A-300D according to embodiments of the present disclosure. Referring to FIGS. 4A to 4D, semiconductor packages 300A-300D according to embodiments of the present disclosure may include semiconductor devices 100A and 100B stacked on package substrates 200A and 200B, respectively. The package substrates 200A and 200B and the semiconductor devices 100A and 100B may be bonded and connected with each other using solder bumps SB.

Referring to FIG. 4A, with further reference to FIGS. 1A and 3A, the barrier layers 140 on which the first bump pillars 151 do not disposed of the semiconductor device 100A and the first land pillars 251 of the package substrate 200A may be electrically and physically connected with each other using the solder bumps SB, and the first bump pillars 151 of the semiconductor device 100A and the bump lands 220 on which the first land pillars 251 do not disposed of the package substrate 200A may be electrically and physically connected with each other using the solder bumps SB. The first bump pillars 151 of the semiconductor device 100A and the first land pillars 251 of the package substrate 200A may be alternately arranged with each other. Accordingly, the first bump pillars 151 of the semiconductor device 100A and the first land pillars 251 of the package substrate 200A may not be aligned and connected with each other.

Referring to FIG. 4B, with further reference to FIGS. 1A and 3B, the barrier layers 140 on which the first bump pillars 151 do not disposed of the semiconductor device 100A and the first land pillars 251 of the package substrate 200B may be electrically connected or physically connected with each other using the solder bumps SB, and the first bump pillars 151 of the semiconductor device 100A and the second land pillars 252 of the package substrate 200B may be electrically and physically connected with each other using the solder bumps SB.

Referring to FIG. 4C, with further reference to FIGS. 2A and 3A, the first bump pillars 151 of the semiconductor device 100B and the bump lands 220 on which the first land pillars 251 do not disposed of the package substrate 200A may be electrically and physically connected with each other using the solder bumps SB, and the second bump pillars 152 of the semiconductor device 100B and the first land pillars 251 of the package substrate 200A may be electrically and physically connected with each other using the solder bumps SB.

Referring to FIG. 4D, with further reference to FIGS. 2A and 3B, the first bump pillars 151 of the semiconductor device 100B and the second land pillars 252 of the package substrate 200B may be electrically and physically connected with each other using the solder bumps SB, and the second bump pillars 152 of the semiconductor device 100B and the first land pillars 251 of the package substrate 200B may be electrically and physically connected with each other using the solder bumps SB.

As shown in FIGS. 4A to 4D, each of the I/O pads 120 and each of the bump lands 220 may be vertically aligned with each other. For example, the I/O pad 120, the barrier layer 140, the first bump pillar 151 or the second bump pillar 152, the solder bump SB, the first land pillar 251 or the second land pillars 252, and the bump lands 220, corresponding each other may be vertically aligned. Each of the first bump pillars 151 and each of the first land pillars 251 may be exclusively arranged not to be vertically aligned each other. Each of the second bump pillars 152 and each of the second land pillars 252 may also be exclusively arranged not to be vertically aligned. Each of the first bump pillars 151 and each of the second land pillars 252 may be vertically aligned. Each of the second bump pillars 152 and each of the first land pillars 251 may be vertically aligned.

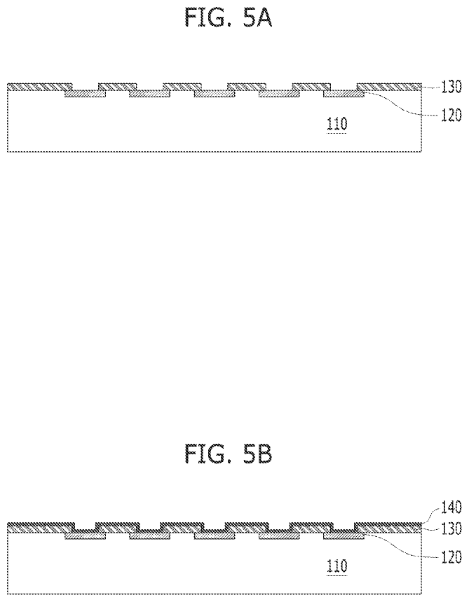

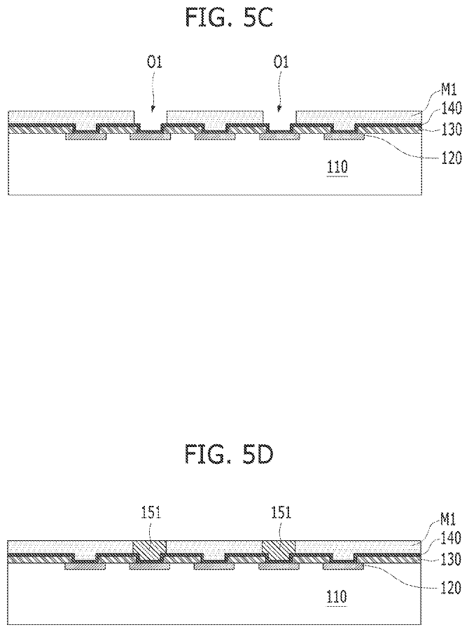

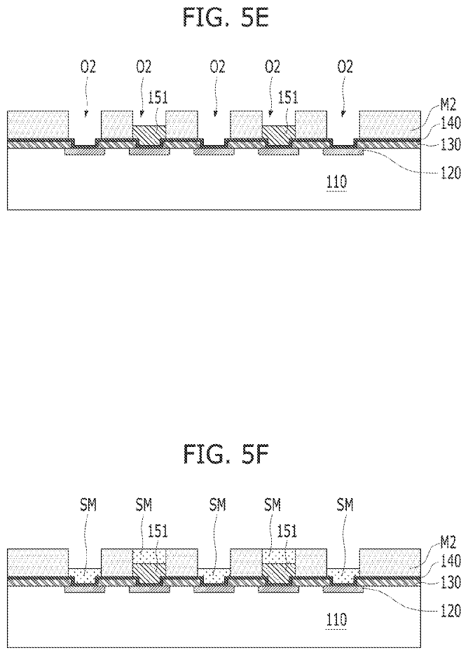

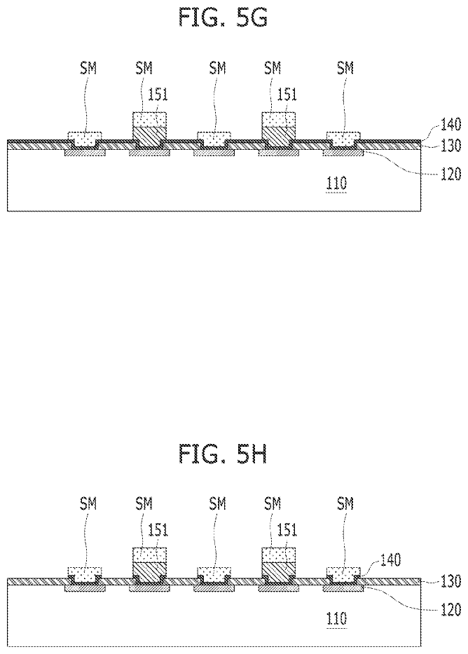

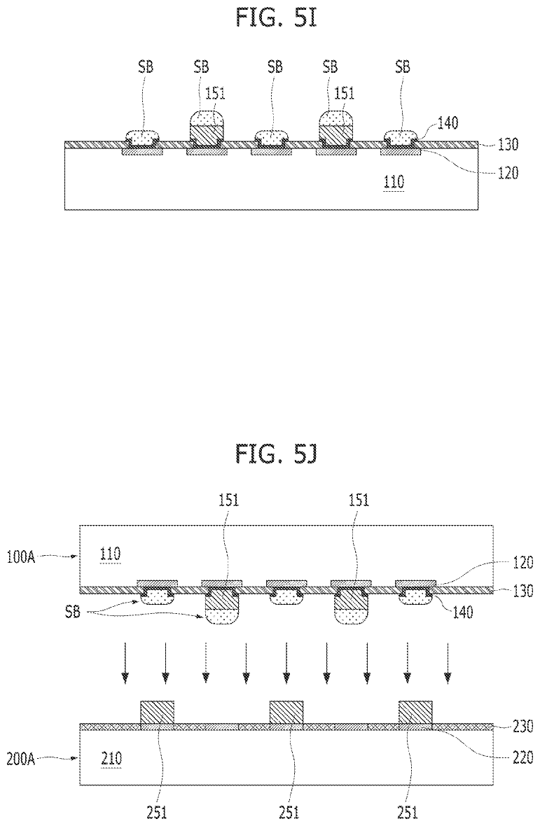

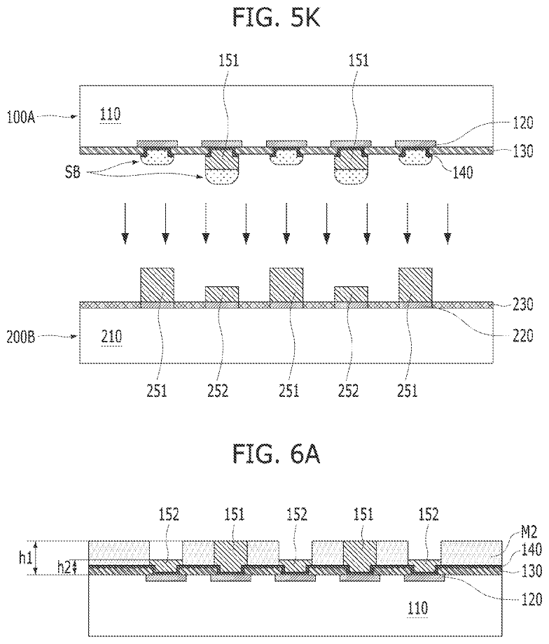

FIGS. 5A to 5D are longitudinal cross-sectional views illustrating a method of manufacturing a semiconductor device according to an embodiment of the present disclosure, and FIG. 5E to 5K are cross-sectional views illustrating methods manufacturing semiconductor packages according to embodiments of the present disclosure using the semiconductor device. Referring to FIG. 5A, a method of manufacturing a semiconductor device according to an embodiment of the present disclosure may include forming a passivation layer 130 on a semiconductor substrate 110 having I/O pads 120. The semiconductor substrate 110 may include a silicon wafer. The semiconductor substrate 110 may include internal circuits and a plurality of insulating layers. The internal circuits may include a plurality of transistors, a plurality of metal vias, multi-layered metal interconnections, and the I/O pads 120. The I/O pads 120 may include a metal such as aluminum (Al). Forming the passivation layer 130 may include performing a coating process or a deposition process, and a photolithography process to form the passivation layer 130 on the semiconductor substrate 110 such that the I/O pads 120 are partially exposed. That is, the surfaces of the I/O pads 120 may be partially exposed without being covered with the passivation layer 130. The passivation layer 130 may include a polyimide-based insulating material. For example, the passivation layer 130 may include polyimide isoindro quindzoline (PIQ). In an embodiment, the passivation layer 130 may include an inorganic material such as silicon nitride (SiN) or silicon oxide (SiO₂).

Referring to FIG. 5B, the method may further include performing a deposition process such as physical vapor deposition (PVD) or chemical vapor deposition (CVD) to form a barrier layer 140. The barrier layer 140 may be conformally formed on a surface of the passivation layer 130 and an exposed surface of the I/O pads 120. The barrier layer 140 may include a seed layer. The barrier layer 140 may include a lower layer including titanium and an upper layer including copper. For example, the barrier layer 140 may include a Ti/Cu stack layer.

Referring to FIG. 5C, the method may further include forming a first mask pattern M1. The first mask pattern M1 may include first openings O1 vertically aligned with some of the I/O pads 120. The first openings O1 may selectively expose some of the I/O pads 120. For example, the first openings O1 may alternately expose the I/O pads 120 to skip every other one. The barrier layer 140 vertically aligned with some of the I/O pads 120 may be exposed through the first openings O1. The first mask pattern M1 may include a polymeric organic material such as a photoresist. In an embodiment, the first openings O1 may alternately expose the I/O pads 120 by serially skipping every other I/O pad 120 to expose through the opening O1 as shown, for example, in FIG. 5C.

Referring to FIG. 5D, the method may further include forming first bump pillars 151 in the first openings O1. The first bump pillars 151 may be formed by performing a first plating process. The first bump pillars 151 may include a metal such as copper (Cu). Thereafter, the semiconductor device 100A illustrated in FIG. 1A may be manufactured by removing the first mask pattern M1.

Referring to FIG. 5E, the method may further include forming a second mask pattern M2. The second mask pattern M2 may be further formed on the first mask pattern M1. Otherwise, the second mask pattern M2 may be formed after the first mask pattern M1 is removed. The second mask pattern M2 may be formed to be thicker than the first mask pattern M1. The second mask pattern M2 may include second openings O2 vertically aligned with the first bump pillars 151, and the I/O pads 120 being not aligned with the first openings O1. The second openings O2 may expose surfaces of the first bump pillars 151 and surfaces of the barrier layer 140.

Referring to FIG. 5F, the method may further include forming a solder material SM in the second openings O2. The solder material SM may be directly formed on exposed surfaces of the barrier layer 140 and the first bump pillars 151. The solder material SM may include tin (Sn).

Referring to FIG. 5G, the method may further include removing the second mask pattern M2. The second mask pattern M2 may be removed by performing a strip process using chemicals including sulfuric acid or hydrogen peroxide or an ashing process using oxygen plasma. The barrier layer 140 that is not vertically aligned with the I/O pads 120 may be exposed by removing the second mask pattern M2.

Referring to FIG. 5H, the method may further include performing an etching process or a cleaning process to remove the exposed barrier layers 140. The barrier layers 140 under the first bump pillars 151 and the solder material SM may remain between the I/O pads 120 and the first bump pillars 151 and between the I/O pads 120 and the solder material SM.

Referring to FIG. 5I, the method may further include performing a reflow process to transform the solder material SM into hemispherical shaped solder bumps SB. The reflow process may include heating the solder material SM to a suitable temperature between about from 120° C. to 250° C.

Referring to FIG. 5J, the method may further include heating and pressing the semiconductor device 100A on the package substrate 200A shown in FIG. 3A. The semiconductor package 300A shown in FIG. 4A may be manufactured.

Referring to FIG. 5K, the method may include heating and pressing the semiconductor device 100A on the package substrate 200B shown in FIG. 3B. The semiconductor package 300B shown in FIG. 4B may be manufactured.

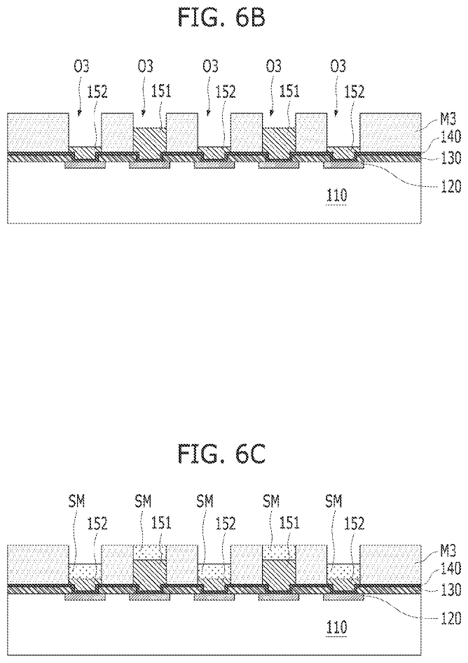

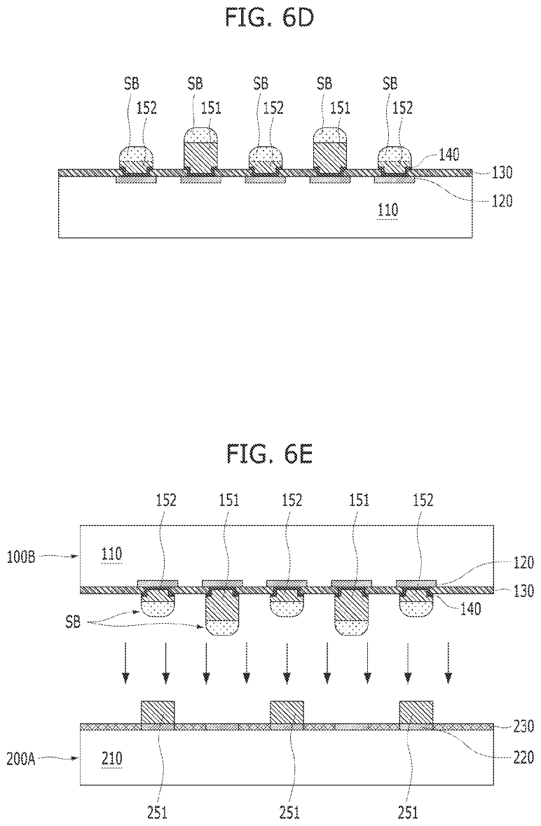

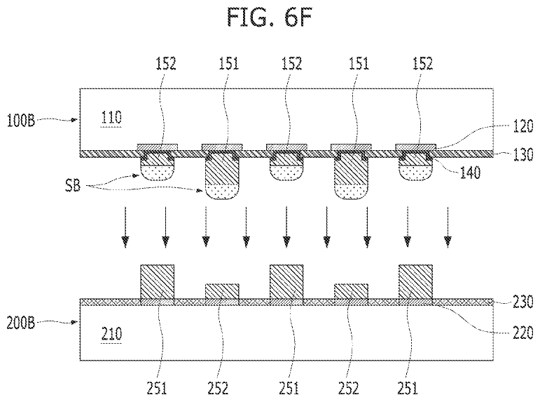

FIG. 6A is a longitudinal cross-sectional view illustrating a method of manufacturing a semiconductor device according to an embodiment of the present disclosure, and FIG. 6B to 6F are cross-sectional views illustrating a method of manufacturing semiconductor packages according to embodiments of the present disclosure using the semiconductor device. Referring to FIG. 6A, a method of manufacturing a semiconductor device according to an embodiment of the present disclosure may include performing the processes described with reference to FIG. 5A to 5E, and performing a second plating process to form first bump pillars 151 and second bump pillars 152 in the second openings O2. The first bump pillars 151 may be vertically thicker than the second bump pillars 152. The first bump pillars 151 may have a first height h1, and the second bump pillars 152 may have a second height h2. The first height h1 may be greater than the second height h2.

Referring to FIG. 6B, the method may further include forming a third mask pattern M3. The third mask pattern M3 may be further formed on the second mask pattern M2. Otherwise, the third mask pattern M3 may be formed after the second mask pattern M2 is removed. The third mask pattern M3 may have third openings O3 exposing surfaces of the first bump pillars 151 and the second bump pillars 152.

Referring to FIG. 6C, the method may further include forming a solder material SM in the third openings O3. The solder material SM may be directly formed on surfaces of the first bump pillars 151 and the second bump pillars 152 exposed in the third openings O3.

Referring to FIG. 6D, the method may further include performing the processes described with reference to FIG. 5G to 5I to remove the third mask pattern M3, performing an etching process or a cleaning process to remove the exposed barrier layers 140, and performing a reflow process to transform the solder material SM into hemispherical shaped solder bumps SM.

Referring to FIG. 6E, the method may further include heating and pressing the semiconductor device 100B on the package substrate 200A shown in FIG. 3A. The semiconductor package 300C shown in FIG. 4C may be manufactured.

Referring to FIG. 6F, the method may include heating and pressing the semiconductor device 100B on the package substrate 200B shown in FIG. 3B. The semiconductor package 300D shown in FIG. 4D may be manufactured.

According to various embodiments of the present disclosure, the distance between solder bumps can be increased, and the spacing and pitch of I/O pads of the semiconductor device, the spacing and pitch of bump pillars of the package substrate, and the spacing and pitch of bump lands of the package substrate can be reduced. In some embodiments, the spacing and pitch of the land pillars of the substrate may be reduced. Accordingly, in some embodiments, high integration and miniaturization of the semiconductor device, the package substrate, and the semiconductor package can be improved.

Although the present disclosure has been specifically described according to the above-described preferred embodiments, it should be noted that the above-described embodiments are for the purpose of explanation and not for the limitation thereof. In addition, it will be appreciated by person having ordinary skill in the art that various embodiments are possible within the scope of the present disclosure.

What is claimed is:

1. A semiconductor device comprising:
a substrate;
input/output (I/O) pads disposed at an upper portion of the semiconductor substrate; and
first bump pillars disposed over the I/O pads,
wherein the first bump pillars are selectively arranged over some of the I/O pads in a first horizontal direction.

2. The semiconductor of claim 1,
wherein the first bump pillars are arranged to skip being disposed over every other one of the I/O pads in the first horizontal direction.

3. The semiconductor of claim 2,
wherein the first bump pillars are arranged to skip being disposed over every other one of the I/O pads in a second horizontal direction, the second horizontal direction being substantially perpendicular to the first horizontal direction.

4. The semiconductor of claim 1, further comprising:
second bump pillars over the I/O pads to be alternatively arranged to the first bump pillars in the first horizontal direction.

5. The semiconductor of claim 4,
wherein the first bump pillars and the second bump pillars are alternately arranged over the I/O pads in a second horizontal direction, the second horizontal direction being substantially perpendicular to the first horizontal direction.

6. The semiconductor of claim 4, wherein:
the first bump pillars have a first vertical height,
the second bump pillars have a second vertical height, and
the first vertical height is greater than the second vertical height.

7. A semiconductor package comprising a semiconductor device stacked over a package substrate,
wherein the semiconductor device comprises:
a semiconductor substrate;
input/output (I/O) pads disposed adjacent to one surface of the semiconductor substrate; and
first bump pillars disposed over the I/O pads,
wherein the first bump pillars are selectively arranged over some of the I/O pads in a first horizontal direction,
wherein the package substrate comprises:
a base layer; and
bump lands disposed at an upper portion of the base layer,
wherein each of the bump lands is vertically aligned with each of the I/O pads.

8. The semiconductor package of claim 7, further comprising:
solder bumps disposed between the first bump pillars and the bump lands.

9. The semiconductor package of claim 7,
wherein the package substrate further includes first land pillars disposed over some of the bump lands in the first horizontal direction.

10. The semiconductor package of claim 9,
wherein each of the first bump pillars and each of the first land pillars are not vertically aligned with each other.

11. The semiconductor package of claim 9,
wherein the package substrate further includes second land pillars disposed over the bump lands to be alternatively arranged with the first land pillars in the first horizontal direction.

12. The semiconductor package of claim 11,
wherein a vertical height of the first land pillars is greater than a vertical height of the second land pillars.

13. The semiconductor package of claim 11,
wherein each of the first bump pillars and each of the second land pillars are vertically aligned with each other.

14. The semiconductor package of claim 7,
wherein the semiconductor device further includes second bump pillars disposed over the I/O pads to be alternatively arranged with the first bump pillars in the first horizontal direction.

15. The semiconductor package of claim 14,
wherein the first bump pillars and the second bump pillars are alternatively arranged in a second horizontal direction, the second horizontal direction being substantially perpendicular to the first horizontal direction.

16. The semiconductor package of claim 14,
wherein a height of the first bump pillars is greater than a height of the second bump pillars.

17. A semiconductor package comprising a semiconductor device stacked over a package substrate,
wherein the semiconductor device includes:
a semiconductor substrate;
input/output I/O) pads disposed adjacent to one surface of the semiconductor substrate; and
first bump pillars disposed over the input/out pads,
wherein the first bump pillars are arranged to skip being disposed over every other one of the I/O pads in a first horizontal direction,
wherein the package substrate includes:
a base layer;
bump lands disposed at an upper portion of the base layer; and
first land pillars disposed over the bump lands,
wherein:
the first land pillars are arranged to skip disposed over every other one of the bump lands in the first horizontal direction, and
each of the first bump pillars and each of the first land pillars are exclusively arranged not to be vertically aligned with each other.

18. The semiconductor package of claim 17,
wherein the semiconductor device further includes second bump pillars disposed over the I/O pads to be alternatively arranged with the first bump pillars in the first horizontal direction.

19. The semiconductor package of claim 18,
wherein the package substrate further includes second land pillars disposed over the bump lands to be alternatively arranged with the first land pillars in the first horizontal direction.

20. The semiconductor package of claim 19, wherein:
each of the first bump pillars and each of the second land pillars are vertically aligned with each other, and
each of the second bump pillars and each of the first land pillars are vertically aligned with each other.
